(19) United States
(12) Patent Application Publication
(10) Pub. No.: US 2025/0255165 A1
(43) Pub. Date: Aug. 7, 2025

(54) DISPLAY DEVICE

(71) Applicant: LG Display Co., Ltd., Seoul (KR)

(72) Inventor: Hyunil KO, Paju-si (KR)

(21) Appl. No.: 18/915,104

(22) Filed: Oct. 14, 2024

(30) Foreign Application Priority Data
Feb. 1, 2024 (KR) 10-2024-0016024

(51) Int. Cl. H10K 59/80; H10K 59/131; H10K 59/38

(52) U.S. Cl. CPC H10K 59/8794; H10K 59/131; H10K 59/38

(57) ABSTRACT

Disclosed is a display device according to a first embodiment, including: a display area including pixels; a pad area disposed outside the display area; and a substrate comprising a groove area between the display area and the pad area; and a printed circuit film attached on the pad area, and the groove area may include a groove pattern formed to be convex from a bottom surface of the substrate.

### CROSS-REFERENCE TO RELATED APPLICATION

The present application claims priority to Korea Patent Application No. 10-2024-0016024, filed Feb. 1, 2024, the entire contents of which is incorporated herein for all purposes by this reference.

### BACKGROUND

### Technical Field

The present disclosure relates to a display device.

### Description of the Related Art

With the development of the information society, there has been an increasing demand for a variety of types of image display devices. In this regard, a range of display devices, such as liquid crystal display (LCD) devices, and organic light-emitting diode (OLED) display devices, have recently come into widespread use.

Among various display devices, the OLED device of an emissive type device has advantages of a viewing angle and a contrast ratio as compared with the LCD device. Since an additional backlight unit is not required, the OLED device has a light weight, a thin profile, and a low power consumption. In addition, the OLED device is driven with a low direct current voltage and has a fast response speed. Specifically, the OLED device has a low fabrication cost.

Recently, a demand for the display device requiring the super resolution capable of realizing the augmented reality (AR) or the virtual reality (VR) using such organic light emitting diode display devices or the display device requiring the super resolution at the equivalent level to the level capable of realizing the augmented reality (AR) or the virtual reality (VR) using such organic light emitting diode display devices is increasing.

### BRIEF SUMMARY

An object of the present disclosure is to provide a display device capable of cooling heat generated during a process for attaching a printed circuit film on the display panel.

Another object of the present disclosure is to provide a display device capable of delaying and preventing transfer of the heat, which is generated during the process for attaching the printed circuit film on the display panel, to the display area.

Problems to be solved by the present disclosure is not limited to the above-described ones, and another technical problems may be inferred from a first embodiment below.

One embodiment is a display device according to a first embodiment, including: a display area including pixels; a pad area disposed outside the display area; and a substrate comprising a groove area between the display area and the pad area; and a printed circuit film attached on the pad area, and the groove area may include a groove pattern formed to be convex from a bottom surface of the substrate.

Another embodiment is a display device, including: a display area comprising pixels; a pad area disposed outside the display area; and a substrate comprising a groove area between the display area and the pad area; and a printed circuit film attached on the pad area, and the groove area may include: a first area having a first thickness; and a second area having a second thickness which is smaller than the first thickness.

Other details of the embodiments are included in the detailed description and the accompanying drawings.

During a process for attaching the printed circuit film on the pad area of the display panel of the display device according to the embodiments, heat may be provided to melt the anisotropic conductive film ACF for combining a pad of the pad area with a bump of the printed circuit film. The melted anisotropic conductive film fills a space between adjacent pads and adjacent bumps and thus, may improve adhesion between the display panel and the printed circuit film.

The display device according to the preferred embodiments may be a display device having a small area capable of realizing augmented reality or virtual reality, and a distance between the pad area of the display panel and the display area in which pixels and organic light emitting diodes are disposed may be very short. Therefore, heat provided to attach the printed circuit film on the pad area of the display panel may easily move to the display area and may damage the organic light emitting diodes. In order to prevent or reduce the heat from moving to the display area, positioning the display area and the pad area to be farther from each other may be considered. In this case, an area of the bezel area may increase.

However, the display device according to the embodiments may cool the heat moving from the pad area to the display area by forming a groove area between the pad area and the display area.

The groove area of the display device according to the embodiments may include at least one groove pattern. The inclusion of the concavo-convex structure formed by the groove pattern may delay, block, reduce, or prevent transfer of the heat transferred from the pad area to the display area by not only allowing the transfer path of the heat transferred from the pad area to increase, but also allowing an area contacting the outside air which meets the groove area to increase.

During a process for attaching the printed circuit film on the pad area of the display panel of the display device according to the embodiments, air may be injected into the groove area. Cooling of the heat may be accelerated because the groove area of the display device according to the first embodiment is implemented to be the concavo-convex structure, and therefore, the contact area contacting the air which has been injected into the groove area is increased.

The groove pattern of the display device according to the embodiments may be formed by a laser processing. The display device according to the first embodiment may be a display device having a small area, and therefore, a distance between the pad area of the display panel and the display area in which pixels and organic light emitting diodes are disposed may be very short. Accordingly, if the groove patterns are formed in plural numbers, the groove patterns may be formed with fine spacings. The laser processing makes the processing technology of a fine pitch easily possible, and thus, the display device according to the first embodiment may exquisitely form groove patterns with fine spacings.

The display device according to the embodiments may minimize the bezel area because the display device according to the embodiments includes the groove area and does not require the distance between the display area and the pad area to be increased.

The display device according to the embodiments may cool, block, and delay heat transferring from the pad area to the display area because the display device according to the embodiments includes the groove area. Therefore, damage to the organic light emitting diode may be minimized, thereby improving the lifespan of the display device.

The effects of the present disclosure are not limited to the above-described effects and other effects which are not described herein may be derived by those skilled in the art from the following description of the embodiments of the present disclosure.

### BRIEF DESCRIPTION OF THE SEVERAL VIEWS OF THE DRAWINGS

FIG. 1 is a plan view of a display device according to a first embodiment.

FIG. 2 is a schematic plan view illustrating a pixel, and a color filter layer of a display device according to a first embodiment.

FIG. 3 is a cross-sectional view taken along B-B′ line of FIG. 2.

FIG. 4 is a cross-sectional view of an organic light emitting diode according to FIG. 3.

FIG. 5 is a cross-sectional view of an organic light emitting diode according to a modification example of FIG. 3.

FIG. 6 is a cross-sectional view taken along A-A′ line of FIG. 1.

FIG. 7 is a perspective view illustrating a process for attaching a printed circuit film (COF) on a pad area of a display device according to a first embodiment.

FIG. 8 is a cross-sectional view taken along C-C′ line of FIG. 7.

FIG. 9 is a schematic view showing transfer of heat provided from a bonding tool to a display area.

FIG. 10 is a graph showing a temperature of a display area according to a temperature of a pad area.

FIG. 11 is a plan view of a display device according to a second embodiment.

FIG. 12 is a cross-sectional view taken along D-D′ of FIG. 11.

FIG. 13 is an enlarged view of a Q1 area of FIG. 12.

FIG. 14 is a cross-sectional view according to a modification example of FIG. 13.

FIG. 15 is a cross-sectional view according to a modification example of FIG. 13.

FIG. 16 is a plan view of a display device according to a third embodiment.

FIG. 17 is a plan view of a display device according to a fourth embodiment.

FIG. 18 is a plan view of a display device according to a fifth embodiment.

FIG. 19 is a plan view of a display device according to a sixth embodiment.

FIG. 20 is a plan view of a display device according to a seventh embodiment.

FIG. 21 is a plan view of a display device according to an eighth embodiment.

FIG. 22 is a plan view of a display device according to a ninth embodiment.

FIG. 23 is a plan view of a display device according to a tenth embodiment.

### DETAILED DESCRIPTION

Hereinafter, a first embodiment of the disclosure will be described with reference to the drawings. In this specification, when it is mentioned that a component (or, an area, a layer, a part, etc.) is referred to as being “on”, “connected to” or “combined to” another component, this means that the component may be directly on, connected to, or combined to the other component or a third component therebetween may be present.

Like reference numerals refer to like elements. Additionally, in the drawings, the thicknesses, proportions, and dimensions of components are exaggerated for effective description. “And/or” includes all of one or more combinations defined by related components.

It will be understood that the terms “first” and “second” are used herein to describe various components but these components should not be limited by these terms. The above terms are used only to distinguish one component from another. For example, a first component may be referred to as a second component and vice versa without departing from the scope of the disclosure. The singular expressions include plural expressions unless the context clearly dictates otherwise.

In addition, terms such as “below”, “the lower side”, “on”, and “the upper side” are used to describe a relationship of configurations shown in the drawing. The terms are described as a relative concept based on a direction shown in the drawing.

In various embodiments of the disclosure, the term “include,” “comprise,” “including,” or “comprising,” specifies a property, a fixed number, a step, a process, an element and/or a component, or a combination thereof, but does not exclude presence or addition of other properties, fixed numbers, steps, processes, elements and/or components, or a combination thereof.

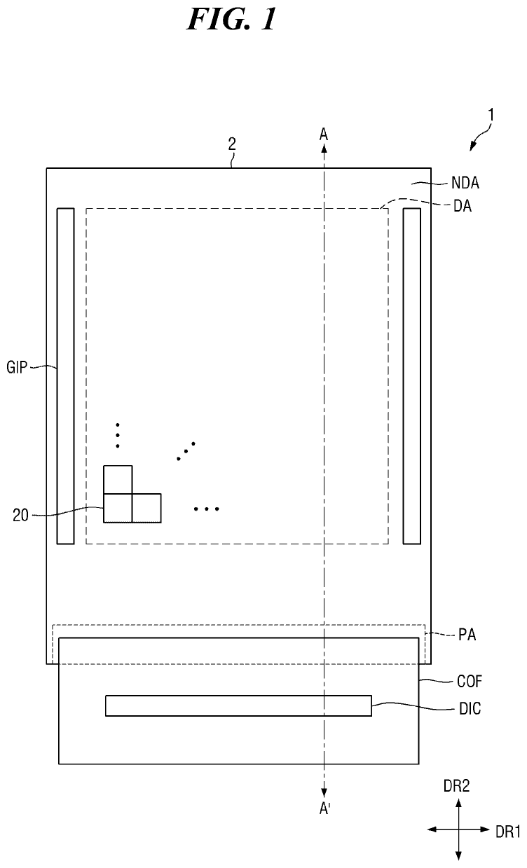

FIG. 1 is a plan view of a display device according to the first embodiment.

Referring to FIG. 1, the display device 100 according to the first embodiment of the present disclosure may include a display area DA including a plurality of pixels 20, and a substrate 2 including a non-display area NDA around the display area DA. The non-display area NDA may surround the display area DA, and may not include a pixel 20, therefore, the non-display area NDA may be an area which does not generate an image, but is not limited thereto. The non-display area NDA may include a pad area PA positioned on the other side of the display area DA in a second direction DR2.

On one side and the other side of the display area DA in the first direction DR1 in the non-display area NDA, a gate driver GIP may be disposed. The gate driver GIP may be formed on the substrate 2 as an integrated circuit, but is not limited thereto, and may be formed as a driver chip. In FIG. 1, it is illustrated that the gate drivers GIP are disposed on right and left sides of the display area DA, but the gate driver GIP is not limited thereto, and one gate driver GIP may be disposed on one side among the right and left sides.

A printed circuit film COF may be attached on the pad area PA. A data driver DIC may be disposed on the printed circuit film COF, for example, but without limitation, in a chip-on-film manner, a tape automated bonding manner or a chip-on-glass manner. The data driver DIC may be provided in the form of a driver chip, but is not limited thereto.

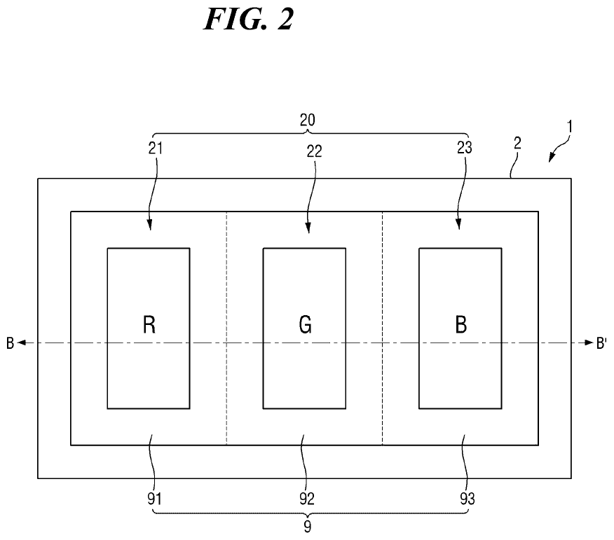

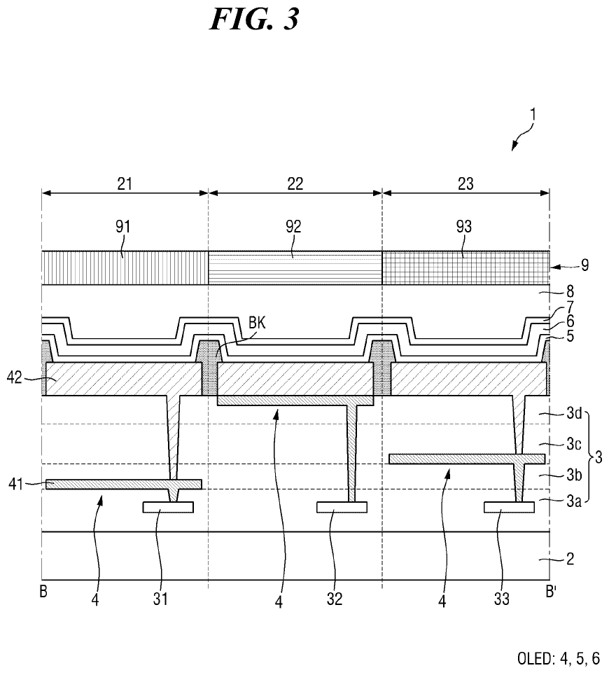

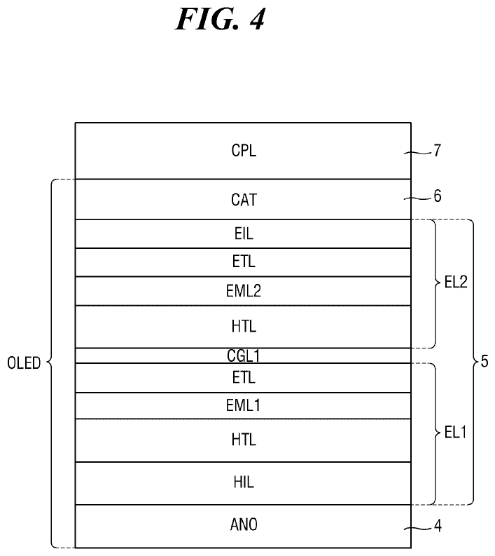

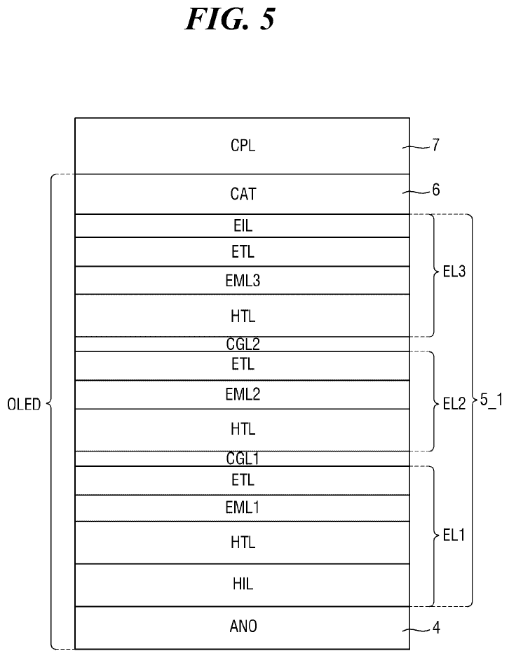

FIG. 2 is a schematic plan view illustrating a pixel, and a color filter layer of the display device according to the first embodiment. FIG. 3 is a cross-sectional view taken along B-B′ line of FIG. 2. FIG. 4 is a cross-sectional view of an organic light emitting diode according to FIG. 3. FIG. 5 is a cross-sectional view of an organic light emitting diode according to a modification example of FIG. 3.

Referring to FIGS. 2 to 5, the display device 1 according to the first embodiment includes the substrate 2, a first electrode 4, a bank BK, a common emitting layer 5, and a second electrode 6.

A plurality of subpixels 21, 22 and 23 are formed on the substrate 2. The plurality of subpixels 21, 22 and 23 may form one pixel. A plurality of pixels may be formed on the substrate 2.

The plurality of subpixels 21, 22 and 23 are formed by including a first subpixel 21, a second subpixel 22, and a third subpixel 23. As the first subpixel 21, the second subpixel 22, and the third subpixel 23 are disposed in the order, the second subpixel 22 may be disposed adjacently on one side, for example, on a left side of the first subpixel 21, and the third subpixel 23 may be disposed adjacently on one side, for example, on a left side of the second subpixel 22.

A description that two subpixels are disposed adjacent to each other must be interpreted throughout the description that another subpixel is not interposed between the two subpixels.

The first subpixel 21 may be configured to emit a red R light, the second subpixel 22 may be configured to emit a blue N light, and the third subpixel 23 may be configured to emit a green G light, but the subpixels are not necessarily limited thereto.

In FIG. 2, it is illustrated that the pixel includes the three subpixels 21, 22 and 23 only, but is not limited thereto. The pixel may include four subpixels. If the pixel includes four subpixels, the pixel may further include a fourth subpixel configured to emit a white W light.

The first to the third subpixels 21, 22 and 23 may be provided in the same size, respectively. For example, each of the first to the third subpixels 21, 22 and 23 may be provided to have the same width and the same height. Here, the width may mean a horizontal direction based on FIG. 2, and the height may mean a perpendicular direction perpendicular to the width based on FIG. 2, but are not limited thereto.

Between the first subpixel 21 and the second subpixel 22, and the second subpixel 22 and the third subpixel 23, banks BK may be disposed, respectively. The bank BK according to the first embodiment is provided to distinguish the first subpixel 21, the second subpixel 22, and the third subpixel 23 from each other. The bank BK may be made of an insulating material containing a black material. The bank BK may be made of, for example, a transparent carbon-based mixture. Specifically, the bank BK may contain carbon black, but is not limited thereto. The bank may also be made of a transparent insulating material.

The first electrode 4 is separately patterned in each of the subpixels 21, 22 and 23. That is, one first electrode 4 is formed in the first subpixel 21, another first electrode 4 is formed in the second subpixel 22, and still another first electrode 4 is formed in the third subpixel 23. The first electrode 4 may function as an anode. The banks BK are provided to cover edges of the first electrodes 4, each of which being disposed in the first to the third subpixels 21, 22 and 23, thereby being able to distinguish the first to the third subpixels 21, 22, and 23 from each other. Therefore, a light emitting area may be defined by the banks BK.

The display device 1 is provided to be a multi-layer including a reflective layer 41 and may further improve light extraction efficiency using a micro-cavity characteristic.

If a distance between the reflective layer 41 and the second electrode 6 becomes an integer multiple of a half wavelength (λ/2) of light emitted from the subpixels, the light is amplified by a constructive interference, whereby an external extraction efficiency of light may be improved by the continuous increase of the amplified light through the reflection and re-reflection process of the light between the reflective layer 41 and the second electrode 6. This property may be referred to as the micro-cavity property.

The common emitting layer 5 may be provided to emit a white light. For example, the common emitting layer 5 may be provided as a two-stack structure including a blue light emitting layer, a yellow-green light emitting layer, and a charge generation layer, or a three-stack structure including a blue light emitting layer, a green light emitting layer, a red light emitting layer, and a charge generation layer so as to emit a white light, but is not necessarily limited thereto, and may be provided as a multi-layer exceeding the three-stack, only if the structure is able to emit a white light.

The common emitting layer 5 may be formed as a common layer disposed throughout the first to the third subpixels 21, 22 and 23. Therefore, the common emitting layer 5 may cover the banks BK disposed between each first electrode 4, which is disposed in each subpixel, and each subpixel. However, the charge generation layer of the common emitting layer 5 may have conductivity. Therefore, if the charge generation layer of the common emitting layer 5 is disposed continuously throughout the first to the third subpixels 21, 22 and 23, color mixing of light may occur in boundaries of the first to the third subpixels 21, 22 and 23 formed between adjacent two subpixels. Therefore, the display device 1 according to the first embodiment may separate the charge generation layer of the common emitting layer 5 in at least one among the boundaries of the adjacent first to the third subpixels 21, 22 and 23. The description in detail thereof will be described below.

The second electrode 6 is configured to form an electric field with the first electrode 4, and may serve as a cathode. The second electrode 6 is disposed on an upper surface of the common emitting layer 5 opposite to a bottom surface of the common emitting layer 5 and may be provided as a common layer disposed throughout the first to the third subpixels 21, 22 and 23.

If the second electrode 6 is a top emission type or a dual emission type, the second electrode 6 may be provided as a transparent electrode, and if the second electrode 6 is a bottom emission type, the second electrode 6 may be provided as an opaque electrode or a reflective electrode. If the second electrode 6 is the top emission type or the dual emission type, the second electrode 6 may be formed as a semi-transparent electrode so as to improve the light extraction efficiency using the micro-cavity characteristic. In the top emission type or the dual emission type, the display device improves light extraction efficiency using the micro-cavity characteristic, and therefore, the present disclosure will be described based on the assumption that the second electrode 6 is formed as the semi-transparent electrode.

The color filter layers 9 are provided in each of the first to the third subpixels 21, 22 and 23, so as to block a certain color from the light emitting from the light emitting layers of the each subpixel. A first color filter 91 provided in the first subpixel 21 may be provided to block light having the rest colors except a red R light. In this case, the first color filter 91 may be provided as a red color filter. A second color filter 92 provided in the second subpixel 22 may be provided to block light having the rest colors except a blue B light. In this case, the second color filter 92 may be provided as a blue color filter. A third color filter 93 provided in the third subpixel 23 may be provided to block light having the rest colors except a green G light. In this case, the third color filter 93 may be provided as a green color filter. However, the embodiment is not limited thereto.

The first to the third color filters 91, 92 and 93 provided in each of the first to the third subpixels 21, 22 and 23 may be provided in the same size as a size of each of the subpixels, or may be provided to be downsized or expanded at a certain ratio corresponding to the size of each subpixels.

Hereinafter, a stacking structure of the display device 1 according to the first embodiment will be described in detail.

The display device 1 according to the first embodiment may include the substrate 2, an insulation layer 3, the first electrode 4, the bank BK, the common emitting layer 5, the second electrode 6, a capping layer 7, an encapsulation layer 8, and a color filter layer 9.

The substrate may be a plastic film, a glass substrate, or a semiconductor substrate such as silicon. For example, the substrate 2 may include glass, plastic, or a flexible polymer film. The flexible polymer film may be made of any one of polyethylene terephthalate (PET), polycarbonate (PC), acrylonitrile-butadiene-styrene copolymer (ABS), polymethyl methacrylate (PMMA), polyethylene naphthalate (PEN), polyether sulfone (PES), cyclic olefin copolymer (COC), triacetylcellulose (TAC) film, polyvinyl alcohol (PVA) film, polyimide (PI) film, and polystyrene (PS), which is only an example and is not necessarily limited thereto.

The substrate 2 may be formed of a transparent material, or an opaque material. On the substrate 2, the first subpixel 21, the second subpixel 22, and the third subpixel 23 are provided. The first subpixel 21 may be provided to emit the red R light, the second subpixel 22 may be provided to emit the blue B light, and the third subpixel 23 may be provided to emit the green G light.

The display device 1 according to the first embodiment is configured as the top emission type by which the emitted light is discharged upward, and therefore, the material of the substrate 2 may be the transparent material, as well as the opaque material. On each of upper portions of the first to the third subpixels 21, 22 and 23 from which the above-mentioned lights are emitted, the color filters 91, 92 and 93 may be provided to transmit light having the above-mentioned colors.

The insulation layer 3 may be formed on the substrate 2. The insulation layer 3 may include a plurality of stacked insulation layers 3a, 3b, 3c and 3d. The insulation layers 3a, 3b, 3c and 3d according to the first embodiment may be stacked sequentially in a thickness direction, and may include the same material as each other. However, the embodiment is not limited thereto, and the insulation layers 3a, 3b, 3c and 3d may include different materials from each other. In the insulation layer 3, a circuit element which includes a plurality of thin film transistors 31, 32 and 33, various signal wirings, and a capacitor, etc., are provided in each of the subpixels 21, 22 and 23. The signal wirings may be formed to include a gate line, a data line, a power line, and a reference line, and the thin film transistors 31, 32 and 33 may be formed to include a switching thin film transistor, a driving thin film transistor, and a sensing thin film transistor. Each of the subpixels 21, 22 and 23 is defined by a cross structure in which the gate line and the data line cross each other.

The switching thin film transistor serves to supply a data voltage which has been switched according to a gate signal supplied to the gate line and is supplied from the data line to the driving thin film transistor.

The driving thin film transistor serves to generate a data current from power supply which has been switched according to a data voltage supplied from the switching thin film transistor and is supplied from the power line, and to supply the data current to the first electrode 4.

The sensing thin film transistor serves to sense a threshold voltage difference of the driving thin film transistor, which is a cause of image quality degradation, and to supply the current of the driving thin film transistor to the reference line in response to a sensing control signal supplied from the gate line or a separate sensing line.

The capacitor serves to maintain a data voltage being supplied to the driving thin film transistor for one frame, and is connected to a gate terminal and a source terminal of the driving thin film transistor, respectively.

A first transistor 31, a second transistor 32, and a third transistor 33 are disposed in each of the subpixels 21, 22 and 23 in a first insulation layer 3a. The first transistor 31 is connected to the first electrode 4 disposed in the first subpixel 21 and applies a driving voltage for emitting light in a color corresponding to the first subpixel 21.

The second transistor 32 is connected to the first electrode 4 disposed in the second subpixel 22 and applies a driving voltage for emitting light in a color corresponding to the second subpixel 22.

The third transistor 33 is connected to the first electrode 4 disposed in the third subpixel 23 and applies a driving voltage for emitting light in a color corresponding to the third subpixel 23.

Each of the first subpixel 21, the second subpixel 22, and the third subpixel 23 is configured to supply a certain current to the light emitting layer according to a data voltage of a data line, if a gate signal is input from a gate line, using each of the transistors 31, 32 and 33. Therefore, each of the first subpixel 21, the second subpixel 22, and the third subpixel 23 may emit light at a certain brightness according to a certain current.

The first insulation layer 3a may protect the transistors 31, 32 and 33. The first insulation layer 3a may be formed of an organic insulation material, but is not necessarily limited thereto, and may be formed of an inorganic insulation material. The transistors 31, 32 and 33 may be positioned in the first insulation layer 3a.

The first electrode 4 of the first subpixel 21, or a reflective layer to be described later may be disposed in the first insulation layer 3a.

The first electrode 4 is separately patterned in each of the subpixels 21, 22 and 23. The first electrode 4 is connected to the driving thin film transistor provided in the insulation layer 3. In more detail, the first electrode 4 is connected to a source terminal or a drain terminal of the driving thin film transistor. To this end, a contact hole for exposing the source terminal or the drain terminal of the driving thin film transistor is formed in the insulation layer 3, and the first electrode 4 is connected to the source terminal or the drain terminal of the driving thin film transistor through the contact hole.

The display device 1 is configured as the top emission type, and to this end, the first electrode 4 may be provided to reflect light, which is emitted from the common emitting layer 5, upward. In this case, the first electrode 4 may be formed of a two-layer structure comprised of the reflective layer 41 for reflecting light (or a reflective electrode or a reflection plate), and a transparent layer 42 for supplying holes to the common emitting layer 5 (or the transparent electrode or ITO electrode or an anode electrode).

The reflective layer 41 may reflect light which is irradiated toward the reflective layer 41, among light emitted from the common emitting layer 5 of each of subpixels 21, 22 and 23, toward the second electrode 6, or the encapsulation layer 8. In addition, the reflective layer 41 is configured to realize the micro-cavity characteristic through the reflection and the re-reflection. To this end, the reflective layer 41 may include a light reflective material for reflecting light. For example, the light reflective material may be metal, but is not necessarily limited thereto, and may be another material if only the material is able to reflect light.

The reflective layer 41 is disposed at a position relatively lower than the common emitting layer 5 configured to emit light, and therefore, the reflective layer 41 may reflect light, which is emitted from the common emitting layer 5, upward. Here, the upward means a direction in which the user can recognize light, for example, a direction in which the encapsulation layer 8 or the color filter layer 9 is disposed. Accordingly, the light efficiency of the first to the third subpixels 21, 22 and 23 may be further improved compared to a case in which no reflective layer 41 is provided, and the user may recognize images with high brightness, that is, vivid images, through the improved light efficiency.

The reflective layer 41 may be disposed inside the insulation layer 3. For example, as illustrated in FIG. 3, the reflective layer 41 disposed in the first subpixel 21 may be disposed such that an upper surface of the first insulation layer 3a or a bottom surface of a second insulation layer 3b and a bottom surface of the reflective layer 41 may be positioned in the same line, the reflective layer 41 disposed in the second subpixel 22 may be disposed such that an upper surface of a fourth insulation layer 3d and an upper surface of the reflective layer 41 may be positioned in the same line, and the reflective layer 41 disposed in the third subpixel 23 may be disposed such that an upper surface of the second insulation layer 3b or a bottom surface of the third insulation layer 3c and the bottom surface of the reflective layer 41 may be positioned in the same line.

The reflective layer 41 of each of the subpixels 21, 22 and 23 may be electrically connected to the transistors 31, 32 and 33 below the reflective layer 41 through the contact hole and a connection electrode.

The reflective layer 41 disposed in the first subpixel 21 may be positioned the most adjacent to the substrate 2, the reflective layer 41 disposed in the third subpixel 23 may be positioned adjacent to the substrate 2, and last, the reflective layer 41 disposed in the second subpixel 22 may be positioned farthest from the substrate 2. Conversely, the reflective layer 41 disposed in the first subpixel 21 may be positioned farthest from the second electrode 6, the reflective layer 41 disposed in the third subpixel 23 may be positioned far from the second electrode 6, and last, the reflective layer 41 disposed in the second subpixel 22 may be positioned the most adjacent to the second electrode 6.

As such, the reason the reflective layer 41 is formed to have various separation distances (or resonance distance) to the second electrode 6 is that extraction efficiency of light in each different color can be improved through reflection and re-reflection between the reflective layer 41 and the second electrode 6 according to the separation distances. Therefore, the light extraction efficiency of red light may be improved in the first subpixel 21, the light extraction efficiency of blue light may be improved in the second subpixel 22, and the light extraction efficiency of green light may be improved in the third subpixel 23.

The transparent layer 42 is disposed over the reflective layer 41. The transparent layer 42 is configured to provide the common emitting layer 5 with holes. The transparent layer 42 may be provided to be transparent so that light reflected from the reflective layer 41 can proceed upward. The transparent layer 42 may be provided to be a transparent material, but is not limited thereto, and may be provided as a metal material in the form of a thin film if the material is able to transmit light. In addition, the present specification has been described in an assumption that the first electrode 4 is a two-layer structure, but the structure of the first electrode 4 may be formed to have more layers. For example, the first electrode 4 may be formed to include a metal material with high reflectance such as a stacking structure of aluminum and ITO (ITO/AI/ITO), an APC alloy, and a stacking structure of an APC alloy and ITO (ITO/APC/ITO). The APC alloy is an alloy of silver (Ag), palladium (Pb), and copper (Cu).

The transparent layer 42 may directly contact the reflective layer 41 to be electrically connected to the reflective layer 41, or may indirectly contact the reflective layer 41, through the connection electrode and the contact hole, to be electrically connected to the reflective layer 41. As the reflective layer 41 is connected to the first to the third transistors 31, 32 and 33 through another contact hole, the reflective layer 41 may apply a driving voltage provided by each of the first to the third transistors 31, 32 and 33 to the transparent layer 42. The transparent layer 42 may provide the common emitting layer 5 with holes when the driving voltage is applied from the first to the third transistors 31, 32 and 33. The transparent layer 42 may directly contact the reflective layer 41 in the second subpixel 22, but is not limited thereto.

The transparent layer 42 may be disposed in each of the first to the third subpixels 21, 22 and 23 in a manner of having almost the same height on an upper surface of the reflective layer 41 or the insulation layer 3. In addition, the reflective layer 41 may be provided to have the same width as that of the transparent layer 42, but is not necessarily limited thereto, and may be provided to have a wider width than that of the transparent layer 42 so as to increase the quantity of light reflected upward.

The banks BK may be provided to cover edges of the first electrodes 4, or edges of the first electrodes 4 and the reflective layer. The banks BK may be disposed in boundaries between the adjacent subpixels 21, 22 and 23.

The banks BK may be formed to surround and cover edges of the transparent layer 42 over the insulation layer 3. Therefore, as illustrated in the cross-sectional view of FIG. 2, the banks BK may cover both ends of the transparent layers 42 provided in each of the first to the third subpixels 21, 22 and 23. In more detail, the banks BK may be formed to cover some of an upper surface and a side surface of the transparent layer 42 at both ends thereof, and some of an upper surface of the insulation layer 3, thereby the problem of deterioration of light emission efficiency caused by the concentration of the current at ends of the transparent layer 42 can be prevented or reduced. An upper surface of the transparent layer 42 which is not covered by the bank BK and exposed becomes a light emitting area. The bank BK may be formed as an organic insulation layer or an inorganic insulation layer.

The common emitting layer 5 is formed over the first electrode 4 and the insulation layer 3. The common emitting layer 5 may be formed over the banks BK disposed between the plurality of subpixels 21, 22 and 23. Therefore, the common emitting layer 5 may contact the upper surface of the transparent layer 42 of the first electrode 4. The common emitting layer 5 may contact upper surfaces of the transparent layers 42 exposed by the bank BK, side surfaces of the adjacent banks BK, and upper surfaces of the banks BK.

In some embodiments, a trench portion may be formed in boundaries between subpixels 21 and 22, and between subpixels 22 and 23. The trench portion may be formed in some portion of the banks BK and the insulation layer 3. The trench portion fully penetrates the bank BK, and may retract some of the fourth insulation layer 3d. In FIG. 3, it is illustrated that the common emitting layer 5 is integrally formed throughout the subpixels 21, 22 and 23, without any physical separation, but the common emitting layer 5 may physically be separated from the trench portion. With this configuration, a leakage current may be prevented or reduced from flowing to any adjacent subpixels 21, 22 and 23 from any one subpixel 21, 22 and 23. The characteristic of which the common emitting layer 5 is physically separated from the trench portion may be applied to all the embodiments provided hereinafter.

The organic light emitting diode OLED may include the first electrode 4 (ANO), the second electrode 6 (CAT), and the common emitting layer 5 between the first electrode 4 and the second electrode 6.

The common emitting layer 5 may be provided to emit white W light. To this end, the common emitting layer 5 may be configured to include a plurality of stacks configured to emit lights in different colors. In more detail, the common emitting layer 5 may be configured to include a first stack, a second stack and the charge generation layer CGL provided between the first stack and the second stack.

The second electrode 6 is formed on the common emitting layer 5. The second electrode 6 may serve as the cathode of the display device 1. The second electrode 6 may be formed in each of the subpixels 21, 22 and 23 and portions between the subpixels 21 and 22, and between the subpixels 22 and 23, like the common emitting layer 5.

In the display device 1 according to the first embodiment, the second electrode 6 may be formed as a semi-transparent electrode so as to implement white light having light efficiency in the top emission type. Therefore, the micro-cavity effect in each of the first to the third subpixels 21, 22 and 23 may be achieved. If the second electrode 6 is formed as the semi-transparent electrode, while the reflection and re-reflection of light between the second electrode 6 and the reflective layer 41 are repeated, the micro-cavity effect may be achieved, thereby improving the light extraction efficiency.

Meanwhile, the second electrode 6 may be formed along the profile of the common emitting layer 5 because the second electrode 6 is formed on the upper surface of the common emitting layer 5. The common emitting layer 5 is formed along the profile of the transparent layer 42 of the first electrode 4 in the light emitting area, and as a result, the second electrode 6 may be formed along the profile of the transparent layer 42 of the first electrode 4. In addition, a capping layer 7 on the second electrode 6 may be formed along the profile of the second electrode 6.

The capping layer 7 may be formed of an inorganic insulation material, but is not limited thereto. The capping layer 7 may be disposed on the second electrode 6 to protect the organic light emitting diode OLED.

The encapsulation layer 8 is formed over the second electrode 6 and serves to prevent external moisture from permeating into the common emitting layer 5. The encapsulation layer 8 may be formed of an inorganic insulation material or in a structure in which an inorganic insulation material and an organic insulation material are alternately stacked, but is not limited thereto.

The color filter layer 9 is formed on the encapsulation layer 8. The color filter layer 9 may include the first color filter 91 having a red color R provided in the first subpixel 21, the second color filter 92 having a blue color B provided in the second subpixel 22, and the third color filter 93 having a green color G provided in the third subpixel 23, but is not limited thereto.

As illustrated in FIG. 4, the common emitting layer 5 may include a first stack EL1, a second stack EL2, and a first charge generation layer CGL1 provided over the first electrode 4.

The first stack EL1 may be provided on the first electrode 4, and may be formed in a structure in which a hole injecting layer (HIL), a hole transporting layer (HTL), a blue B emitting layer (EML1), and an electron transporting layer (ETL) are sequentially stacked.

The first stack EL1 may be disposed between the first subpixel 21 and the second subpixel 22, and between the second subpixel 22 and the third subpixel 23, that is, the first stack EL1 may be disposed on the banks BK.

The first charge generation layer CGL1 serves to provide the first stack EL1 and the second stack EL2 with charges. The first charge generation layer CGL1 may include a N-type charge generation layer configured to provide the first stack EL1 with an electron, and a P-type charge generation layer configured to provide the second stack EL2 with a hole. The N-type charge generation layer may include a metal material as a dopant.

The first charge generation layer CGL1 may be disposed between the first subpixel 21 and the second subpixel 22, and between the second subpixel 22 and the third subpixel 23, that is, the first charge generation layer CGL1 may be disposed on the banks BK.

The second stack EL2 may be provided on the first stack EL1, and may be formed in a structure in which the hole transporting layer (HTL), a yellowish green YG emitting layer (EML2), the electron transporting layer (ETL), and an electron injecting layer (EIL) are sequentially stacked.

The second stack EL2 may be disposed between the first subpixel 21 and the second subpixel 22, and between the second subpixel 22 and the third subpixel 23, that is, the second stack EL2 may be disposed on the banks BK.

As a result, as illustrated in FIG. 2, the common emitting layer 5 may be provided as a common layer disposed throughout the first to the third subpixels 21, 22 and 23.

As illustrated in FIG. 5, a common emitting layer 5_1 of the organic light emitting diode OLED according to the first embodiment may include the first stack EL1, the second stack EL2, a third stack EL3, the first charge generation layer CGL1 between the first stack EL1 and the second stack EL2, and a second charge generation layer CGL2 between the second stack EL2 and the third stack EL3, provided over the first electrode 4.

The first stack EL1 may be provided on the first electrode 4, and may be formed in a structure in which the hole injecting layer (HIL), the hole transporting layer (HTL), the blue B Emitting Layer (EML1), and the electron transporting layer (ETL) are sequentially stacked.

The first stack EL1 may be disposed between the first subpixel 21 and the second subpixel 22, and between the second subpixel 22 and the third subpixel 23, that is, the first stack EL1 may be disposed on the banks BK.

The first charge generation layer CGL1 serves to provide the first stack EL1 and the second stack EL2 with charges. The first charge generation layer CGL1 may include the N-type charge generation layer configured to provide the first stack EL1 with an electron, and the P-type charge generation layer configured to provide the second stack EL2 with a hole. The N-type charge generation layer may include a metal material as a dopant.

The first charge generation layer CGL1 may be disposed between the first subpixel 21 and the second subpixel 22, and between the second subpixel 22 and the third subpixel 23, that is, the first charge generation layer CGL1 may be disposed on the banks BK.

The second stack EL2 may be provided on the first stack EL1, and may be formed in a structure in which the hole transporting layer (HTL), a green G emitting layer (EML2), and the electron transporting layer (ETL) are sequentially stacked.

The second stack EL2 may be disposed between the first subpixel 21 and the second subpixel 22, and between the second subpixel 22 and the third subpixel 23, that is, the second stack EL2 may be disposed on the banks BK.

The second charge generation layer CGL2 serves to provide the second stack EL2 and the third stack EL3 with charges. The second charge generation layer CGL2 may include the N-type charge generation layer configured to provide the second stack EL1 with an electron, and the P-type charge generation layer configured to provide the third stack EL3 with a hole. The N-type charge generation layer may include a metal material as a dopant.

The second charge generation layer CGL2 may be disposed between the first subpixel 21 and the second subpixel 22, and between the second subpixel 22 and the third subpixel 23, that is, the second charge generation layer CGL2 may be disposed on the banks BK.

The third stack EL3 is disposed on the second stack EL2, and may be formed in a structure in which the hole injecting layer (HIL), a red R emitting layer (EML3), the electron transporting layer (ETL), and the electron injecting layer (EIL) are sequentially stacked.

Referring to FIG. 3 again, the second electrode 6 is disposed on the common emitting layer 5, the encapsulation layer 8 is formed over the second electrode 6, and the color filter layer 9 is formed on the encapsulation layer 8.

Although not illustrated, a black matrix may be provided between the first to the third color filters 91, 92 and 93 so as to prevent or reduce color mixing between the subpixels.

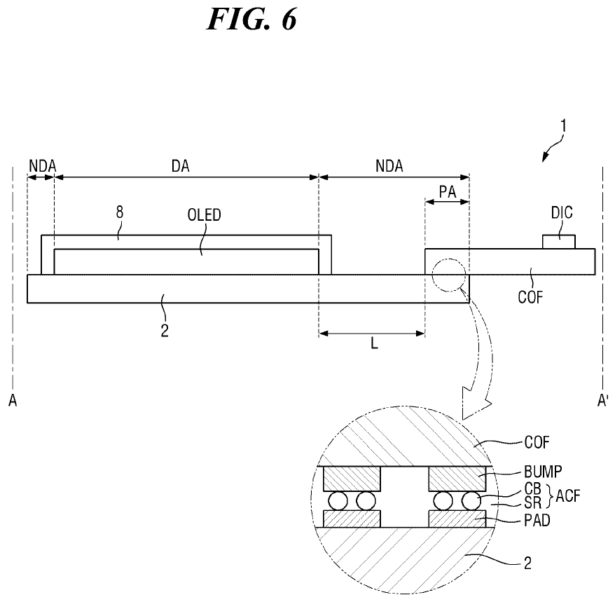

FIG. 6 is a cross-sectional view taken along A-A′ line of FIG. 1. For convenience of description, FIG. 6 only illustrates the organic light emitting diode OLED and the encapsulation layer 8 configured to encapsulate the organic light emitting diode OLED on the substrate 2 of the display device 1.

Referring to FIG. 6, the printed circuit film COF may be attached on the pad area PA of the substrate 2. The data driver DIC may be disposed on the printed circuit film COF. Though it is illustrated in FIG. 6 that the data driver DIC is disposed on an upper surface of the printed circuit film COF, but is not limited thereto, and the data driver DIC may be disposed on a lower surface of the printed circuit film COF.

The non-display area NDA around the display area DA may be a bezel area. The non-display area NDA on a right side of the display area DA may include the pad area PA, and a separation space between the pad area PA and the display area DA. The pad area PA and the display area DA may be spaced apart by a certain spacing L.

The display device 1 may further include a pad PAD on the pad area PA. The pad PAD may be disposed on the same layer as a layer on which one among one conductive layer of the thin film transistors 31, 32 and 33, the reflective layer 41 and the transparent layer 42 is disposed, but is not limited thereto. In the pad area, a plurality of pads PAD may be disposed. In FIG. 6, the plurality of pads PAD are disposed in two rows, but is not limited thereto.

On the lower surface of the printed circuit film COF, a bump BUMP may be disposed. Anisotropic conductive film ACF may be disposed between the bump PUMP and the pad PAD. The anisotropic conductive film ACF may include a resin SR and conductive balls CB distributed in the resin SR. The resin SR may include an organic material having adhesiveness. With the conductive balls CB disposed therebetween, the pad PAD and the bump BUMP may be electrically connected. The resin SR serves to contact a side surface and a lower surface of the bump BUMP, and a side surface and a lower surface of the pad PAD to attach the bump BUMP and the pad PAD to each other.

Meanwhile, if attaching the printed circuit film COF and the pad PAD of the pad area PA to each other through the anisotropic conductive film ACF, the anisotropic conductive film ACF may be melted by heat. The heat to melt the anisotropic conductive film ACF is provided to the pad area PA, and some of the heat may be transferred to the display area DA.

In particular, the substrate 2 of the display device 1 according to the first embodiment may be a semiconductive substrate, and the thermal conductivity of the semiconductor substrate may be 50 W/m·K (watt per meter-kelvin) to 100 W/m·K. For example, the thermal conductivity of a glass substrate may be about 0.8 W/m·K. The thermal conductivity of the semiconductor substrate used in the substrate 2 may be about 62.5 to about 125 times the thermal conductivity of the glass substrate. In addition, the thermal diffusivity of the semiconductor substrate may be about 0.3 cm2/s (square meter per second) to about 0.6 cm2/s. For example, the thermal diffusivity of the glass substrate may be about 0.006 cm2/s. The thermal diffusivity of the semiconductor substrate used in the substrate 2 may be about 50 times to about 100 times the thermal diffusivity of the glass substrate. As such, the thermal conductivity, and the thermal diffusivity of the substrate 2 in which the semiconductor substrate is used may be dramatically greater, respectively, compared to the thermal conductivity and the thermal diffusivity of the substrate 2 in which the glass substrate is used. Therefore, the heat for melting the anisotropic conductive film ACF may be transferred fast and easily from the pad area PA to the display area DA.

The organic light emitting diode OLED in the display area DA may be thermally damaged at a temperature of about 100° C. to about 120° C. or more. During the process for attaching the printed circuit film COF and the pad PAD to each other in the pad area PA through the anisotropic conductive film ACF, in order to prevent or reduce thermal damage to the organic light emitting diode OLDE caused by the heat generated during the process, the display area DA in which the organic light emitting diode OLED is disposed and the pad area PA are spaced apart by the certain spacing L. For example, the minimum certain spacing L may be about 2 mm, but is not limited thereto. However, even if the display area DA and the pad area PA are spaced apart by the certain spacing L in order to prevent or reduce thermal damage to the organic light emitting diode OLED, the thermal damage to the organic light emitting diode OLED may occur. In this case, the certain spacing L may be designed to be about 2 mm or more, but if doing so, the area of the non-display area NDA is widened, leading the bezel area to be expanded.

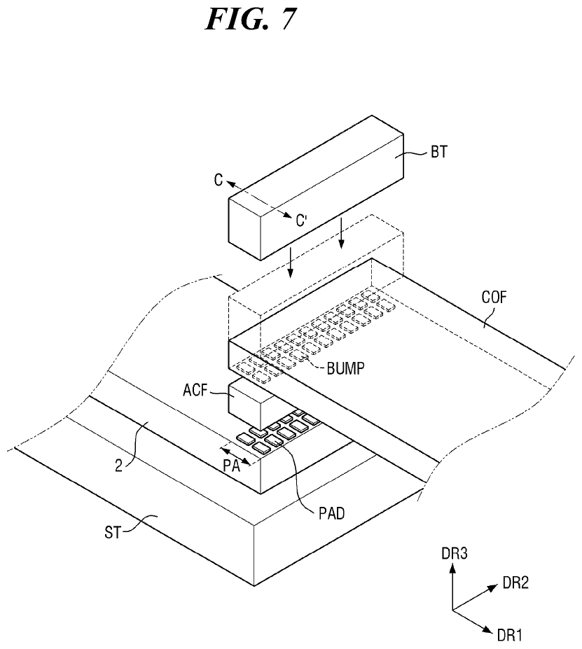

Hereinafter, referring to FIGS. 7 to 9, a process for attaching the printed circuit film COF on the pad area PA of the display device 1 according to the first embodiment will be described in more detail.

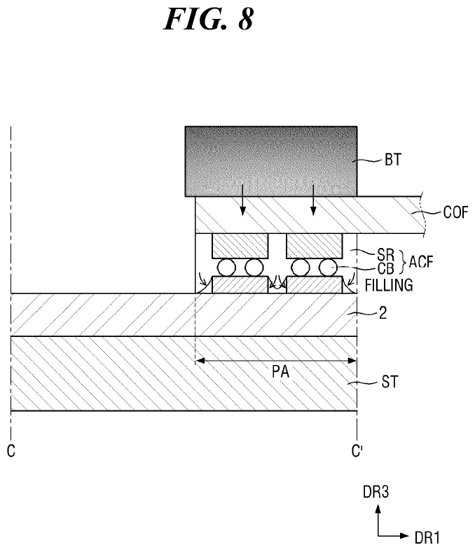

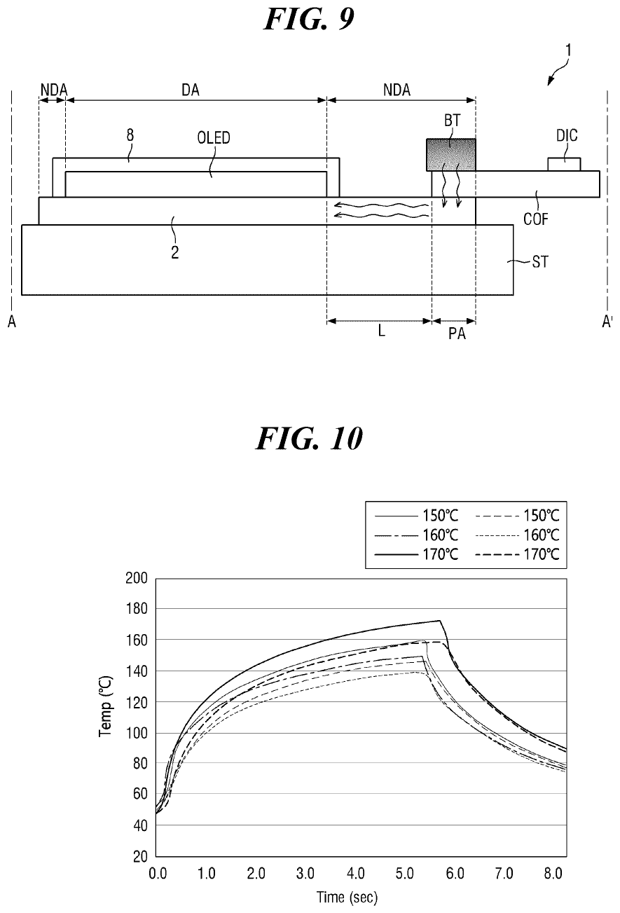

FIG. 7 is a perspective view illustrating a process for attaching the printed circuit film (COF) on the pad area of the display device according to the first embodiment. FIG. 8 is a cross-sectional view taken along C-C′ line of FIG. 7. FIG. 9 is a schematic view showing transfer of heat provided from a bonding tool to the display area. FIG. 10 is a graph showing a temperature of the display area according to a temperature of the pad area.

Referring to FIGS. 7 and 8, the anisotropic conductive film ACF is disposed on the pad area PA, and the printed circuit film COF is disposed on the anisotropic conductive film ACF. A bonding tool BT is disposed on the upper surface of the printed circuit film COF. A stage ST is disposed below the substrate 2.

When pressing the bonding tool BT disposed on the upper surface of the printed circuit film COF, the pad PAD and the bump BUMP may be combined with each other as the resin SR fills spaces between an upper surface and a side surface of the pad PAD, a lower surface and a side surface of the bump BUMP, the adjacent pads PAD, and the adjacent bumps BUMP. However, as illustrated in FIG. 8, a space with which the resin SR is not filled may be generated in a space between adjacent pads PAD because the flowability of the resin SR is weak if using the pressing of the bonding tool BT only. In this case, the adhesion between the pad area PA and printed circuit film COF may be deteriorated.

The resin SR must be melted during the process for pressing the bonding tool BT on the upper surface of the printed circuit film COF in order to increase flowability of the resin SR. To this end, the heat may be provided to the bonding tool BT. The heat provided to an upper end of the bonding tool BT is provided to a lower end of the bonding tool BT in a downward direction. The heat provided to the upper end of the bonding tool BT is partially lost because the bonding tool BT contacts the outside air, and may be provided to the lower end of the bonding tool BT. For example, heat corresponding to a temperature of is provided to the upper end of the bonding tool BT, and heat corresponding to a temperature lower than about 350° C. to about 400° C. may be provided to the lower end of the bonding tool BT. When the heat corresponding to a temperature of about 350° C. to about 400° C. is provided to the upper end of the bonding tool BT, the heat corresponding to a temperature of about 150° C. to about 170° C. may be provided to the pad area PA and the anisotropic conductive film ACF. The resin SR of the anisotropic conductive film ACF is melted by the heat provided to the anisotropic conductive film ACF, and as illustrated in FIG. 8, the resin SR may, for example, fill empty spaces between the adjacent pads PAD, thereby improving the adhesion between the printed circuit film COF and the pad area PA. Meanwhile, to the stage ST, heat at a certain temperature may be provided. For example, during the process for pressing the bonding tool BT on the upper surface of the printed circuit film COF, the stage ST may be in a state in which heat corresponding to a temperature at about 80° C. is provided thereto. During the process for pressing the bonding tool BT on the upper surface of the printed circuit film COF, as the heat corresponding to a temperature at about 80° C. is provided to the stage ST as well, the melting of the anisotropic conductive film ACF may be conducted more easily. When the heat corresponding to a temperature at about 80° C. is provided to the stage ST, thermal damage may be generated in the substrate 2 because the stage ST directly contacts the substrate 2.

Meanwhile, as illustrated in FIG. 9, the heat provided to the pad area PAD may transfer to the display area DA. As described above, the thermal conductivity and the thermal diffusivity of the substrate 2, in which the semiconductor substrate used, of the display device 1 according to the first embodiment is dramatically greater compared to those of the substrate in which the glass substrate is used, respectively, the heat provided to the pad area PA may be transferred to the display area DA without any great loss of the heat.

As illustrated in FIG. 10, if heat corresponding to about 350° C. is provided to the upper end of the bonding tool BT, heat corresponding to about 150° C. is provided to the pad area PA, and heat corresponding to about 139.3° C., which is about 10.5° C. lower than the temperature of the pad area PA, which is about 150° C., is provided to the display area DA. As described above, the organic light emitting diode OLED of the display area DA is thermally damaged at a temperature about 100° C. to about 120° C., therefore, if the heat corresponding to a temperature of about 350° C. is provided to the upper end of the bonding tool BT, the organic light emitting diode OLED may be thermally damaged.

If heats corresponding to about 350° C. or more (about 375° C., about 400° C.) are provided to the upper end of the bonding tool BT in order to more easily melt the anisotropic conductive film ACF, heats corresponding to about 160° C. and about 170° C. are provided to the pad area PA, respectively, and heats corresponding to about 147.1° C. and about 156.8° C., which are 12.3° C. and 13.5° C. lower than the temperature of the pad area PA, which are about 160° C. and about 170° C., respectively, are provided to the display area DA. Likewise, in this case as well, the organic light emitting diode OLED may be thermally damaged.

It is possible to consider a measure for providing heat corresponding to only a threshold temperature (about 100° C. to about 120° C.) of the organic light emitting diode OLED or less to be provided to the organic light emitting diode OLED by decreasing the heat provided to the pad area PAD, however, the melting of the anisotropic conductive film ACF may be smoothly performed only when the temperature of the upper end of the bonding tool BT is about 350° C. or more. In other words, when the temperature of the upper end of the bonding tool BT is lower than about 350° C., it is hard to melt the anisotropic conductive film ACF, therefore, an adhesion fault between the printed circuit film COF and the pad area PA may occur.

Hereinafter, embodiments in which heat corresponding to a temperature of about 350° C. is provided to the bonding tool BT to melt the anisotropic conductive film ACF, and which may prevent or reduce the corresponding heat from being distributed to the display area DA will be described.

While describing the embodiments below, redundant, and detailed description of the same components as the components which have been described with reference to FIGS. 1 to 10 will be omitted.

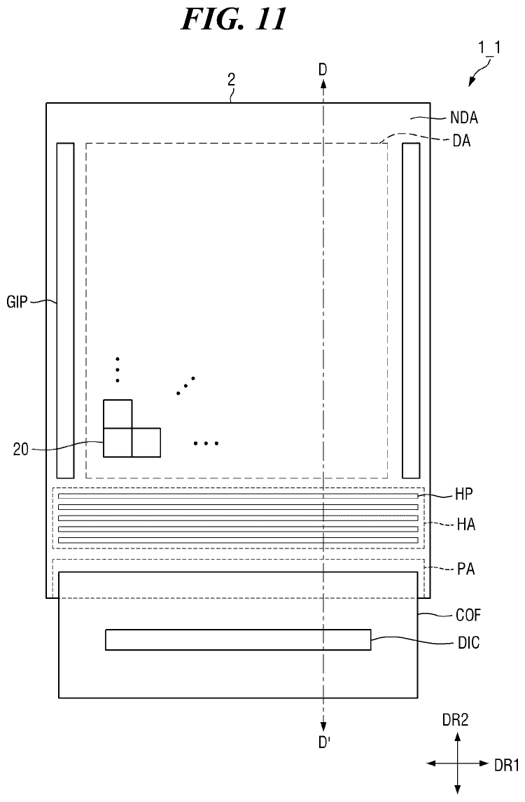

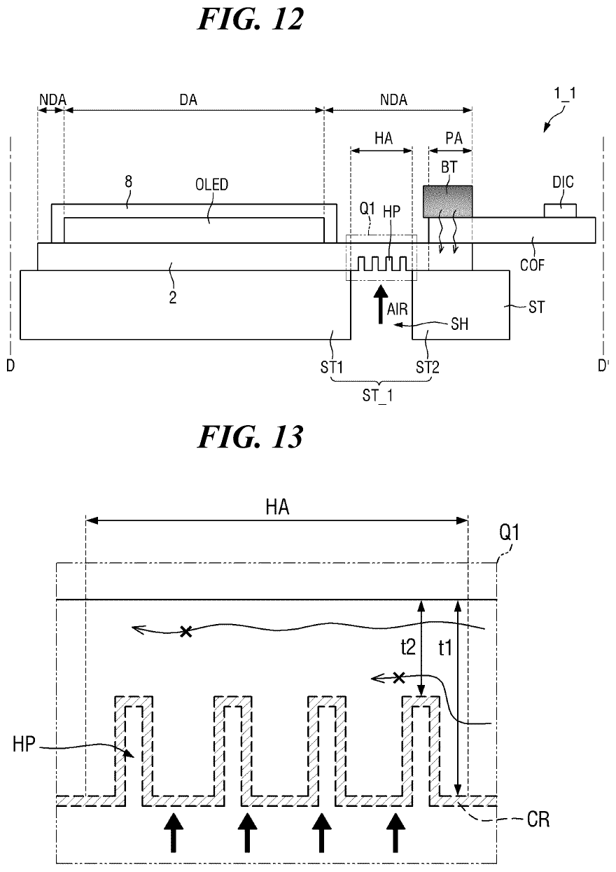

FIG. 11 is a plan view of a display device according to a second embodiment. FIG. 12 is a cross-sectional view taken along D-D′ of FIG. 11. FIG. 13 is an enlarged view of a Q1 area of FIG. 12.

Referring to FIGS. 11 to 13, the non-display area NDA of a display device 1_1 according to the second embodiment may further include a groove area HA formed between the display area DA and the pad area PA. The groove area HA may include a plurality of groove patterns HP. The groove patterns HP may extend along a first direction DR1, and the adjacent groove patterns HP may be spaced apart from each other in a second direction DR2.

The groove patterns HP may be formed from a lower surface to an upper surface of the substrate 2. A thickness t2 of the substrate 2 in which the groove pattern HP is formed and a thickness t1 of the substrate 2 in which the groove pattern HP is not formed may be different from each other. The thickness t2 of the substrate 2 in which the groove pattern HP is formed may be smaller than the thickness t1 of the substrate 2 in which the groove pattern HP is not formed. For example, a ratio of the thickness t2 to the thickness t1 may be in a range of 10% to 60%, particularly, a range of 20% to 50%, more particularly, 35%. As the groove pattern HP is indented from a lower surface to an upper surface of the substrate 2, a concavo-convex structure may be formed in the groove area HA on the lower surface of the substrate 2.

A stage hole SH corresponding to the groove area HA of the substrate 2 may be formed in a stage ST_1. The stage hole SH may fully penetrate the stage ST_1. The stage ST_1 may include a first stage part ST1 overlapping the display area DA, and a second stage part ST2 overlapping the pad area PA on the basis of the stage hole SH. In the cross-sectional view in FIG. 12, it is illustrated that the first stage part ST1 and the second stage part ST2 are physically separated on the basis of the stage hole SH, however, the first stage part ST1 and the second stage part ST2 may be physically connected to each other in an area in which the stage hole SH is not disposed. Air may be injected through the stage hole SH.

As illustrated in FIGS. 12 and 13, during the process for attaching the printed circuit film COF on the pad area PA, heat provided to the pad area PA may be provided to the groove area HA disposed between the display area DA and the pad area PA. The groove area HA includes the plurality of groove patterns HP, and therefore, the concavo-convex structure may be formed on the lower surface of the substrate 2. The concavo-convex structure may increase heat passage in the groove area HA. Therefore, the heat transferred to the groove area HA may be delayed or blocked by the concavo-convex structure.

In addition, the concavo-convex structure formed in the groove area HA may increase an area of a contact area CR in which the substrate 2 and the outside air (outside air meeting the lower surface of the substrate 2) contact. The heat transferred to the groove area HA may be cooled by the outside air, because the contact area in which the substrate 2 and the outside air contact is increased in the groove area HA.

As described above, air may be injected through the stage hole SH to the lower surface of the groove area HA of the substrate 2. As the contact area in which the lower surface of the substrate 2 and the injected air AIR contact is increased because the groove area HA of the display device 1_1 is implemented as the concavo-convex structure, cooling of the heat may be accelerated.

Meanwhile, the groove pattern HP of the groove area HA may be formed by a laser processing. As described above, the display device 1_1 may be a display device having a small area, and the certain spacing L between the pad area PA and the display area DA may be very short. Therefore, if forming the groove patterns HP in plural numbers, the groove patterns HP may be formed with a fine spacing. As the laser processing may easily realize the processing of a fine pitch, the groove patterns HP with fine spacings may be delicately formed in the display device 1_1. In addition, the indentation depth of the plurality of groove patterns HP may be evenly processed compared to that of the wet etching process. If the indentation depths of the plurality of groove patterns HP are different from each other, heat is concentrated in the groove pattern HP having a relatively smaller indentation depth, and the heat may be transferred to the display area DA. According to the display device 1_1 according to the second embodiment, it is advantageous that the heat may be cooled evenly throughout the groove area HA because the groove patterns HP are formed through the laser processing.

Further, as described above, the display device 1_1 may minimize or reduce the bezel area because the display device 1_1 includes the groove area HA, and the heat transferred from the pad area PA to the groove area HA may be cooled without extending the distance between the display area DA and the pad area PA.

Moreover, the groove pattern HP of the display device 1_1 according to the second embodiment is formed in a shape of a line extending in the first direction DR1, and therefore, the groove pattern HP may be perpendicular to a direction of heat transfer from the pad area PA to the groove area HA. That is, the groove pattern HP extends in a direction perpendicular to the direction of the heat transfer, and accordingly, the effect of heat blocking through the groove area HA may become further excellent.

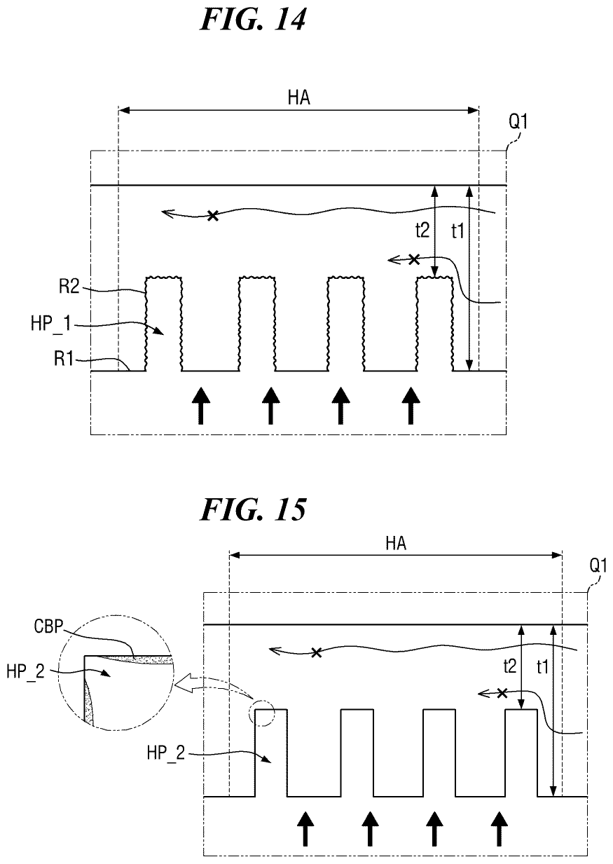

With reference to FIGS. 14 and 15, groove patterns HP_1 and HP_2 formed by the laser processing will be described below.

FIG. 14 is a cross-sectional view according to a modification example of FIG. 13. FIG. 15 is a cross-sectional view according to a modification example of FIG. 13.

Referring to FIG. 14, a coarseness level R2 of the substrate 2 in which a groove pattern HP_1 is formed may be greater than a coarseness level R1 of the substrate 2 in which the groove pattern HP_1 is not formed. If forming the groove pattern HP_1 through the laser processing, there may occur a property change between a surface to which the laser is irradiated and a surface to which the laser is not irradiated which would improve the delay, cooling, prevention or reduction of the heat transfer.

Other descriptions have been provided with reference to FIGS. 11 to 13, description thereof in more detail is omitted.

Referring to FIG. 15, a carbonized surface CBP may be further formed on a surface of the substrate 2 on which the groove pattern HP_2 is formed. When the groove pattern HP_2 is formed by the laser processing, carbonization by the laser may occur on a surface onto which the laser is irradiated. As the carbonized surface CBP is formed, the property of the substrate 2 may be strengthened. For example, the coarseness level of a portion on which the carbonized surface CBP is formed in the substrate 2 may increase. Accordingly, the generated heat may be prevented or reduced from being transferred to the substrate 2, or a degree of heat transfer may be reduced. In addition, in the portion in which the carbonized surface CBP is formed, air bubbles may be generated. The air bubbles may prevent or reduce the heat transfer to the substrate 2 or may reduce the degree of the heat transfer.

Other descriptions have been provided with reference to FIGS. 11 to 13, therefore, description thereof in more detail is omitted.

Hereinafter, a variety of groove pattern changes will be described.

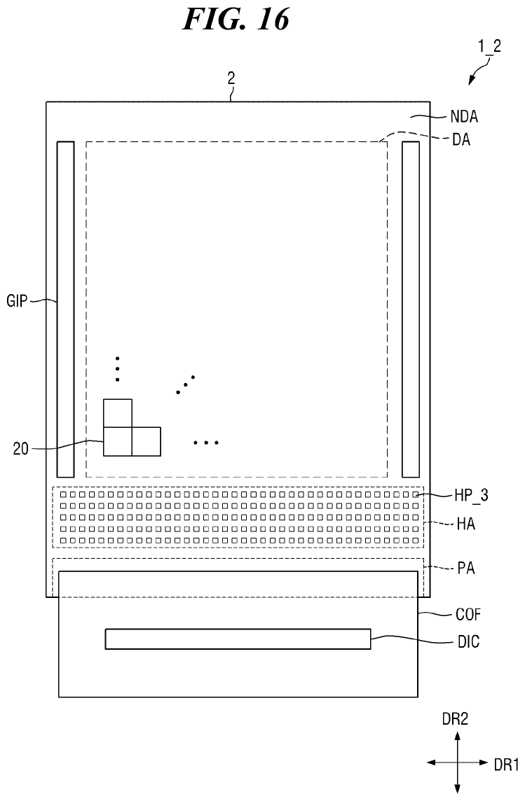

FIG. 16 is a plan view of a display device according to a third embodiment.

Referring to FIG. 16, considering that a plurality of groove patterns HP_3 of a display device 1_2 according to the third embodiment may be disposed in an island form, the display device 1_2 is different from the display device 1_1 according to FIG. 11. The groove pattern HP_3 may take a form of a quadrangle but the present disclosure is not limited thereto, for example, the groove pattern may also be formed in a shape of various polygon islands such as a triangle, a pentagon, a hexagon, etc., The groove patterns HP_3 may be disposed in a matrix form along the first direction DR1 and the second direction DR2.

Other descriptions have been provided with reference to FIGS. 11 to 13, therefore, description thereof in more detail is omitted.

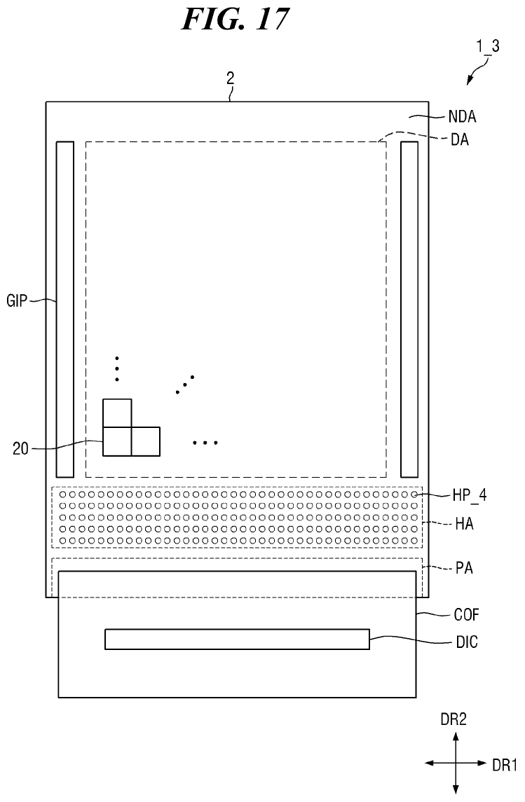

FIG. 17 is a plan view of a display device according to a fourth embodiment.

Referring to FIG. 17, considering that a plurality of groove patterns HP_4 of a display device 1_3 according to the fourth embodiment may be disposed in an island form, the display device 1_3 according to the fourth embodiment is different from the display device 1_1 according to FIG. 11. The groove pattern HP_4 may take a form of a circle, or an oval.

Other descriptions have been provided with reference to FIGS. 11 to 13, therefore, description thereof in more detail is omitted.

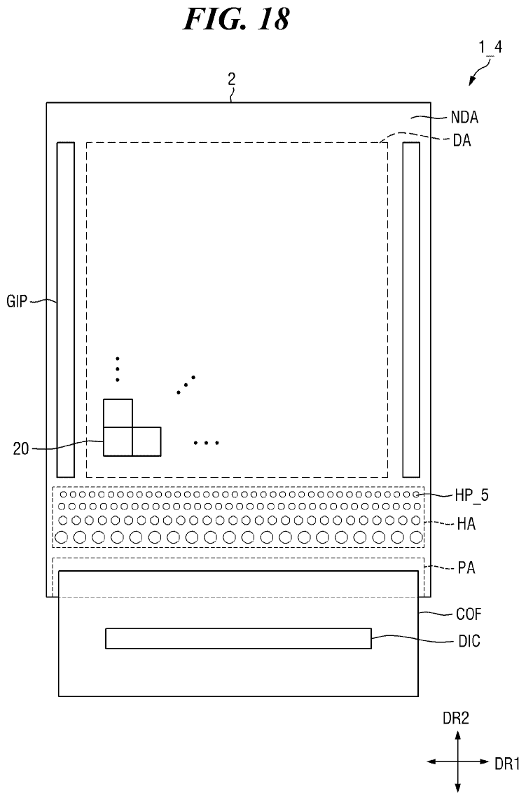

FIG. 18 is a plan view of a display device according to a fifth embodiment.

Referring to FIG. 18, considering that a plurality of groove patterns HP_5 of a display device 1_4 according to the fifth embodiment have different sizes, the display device 1_4 according to the fifth embodiment is different from the display device 1_3 according to FIG. 17. For example, as shown in FIG. 18, the sizes of the groove patterns may become larger as they are closer to the pad area PA, but the present disclosure is not limited thereto.

Other descriptions have been provided with reference to FIGS. 11 to 13, therefore, description thereof in more detail is omitted.

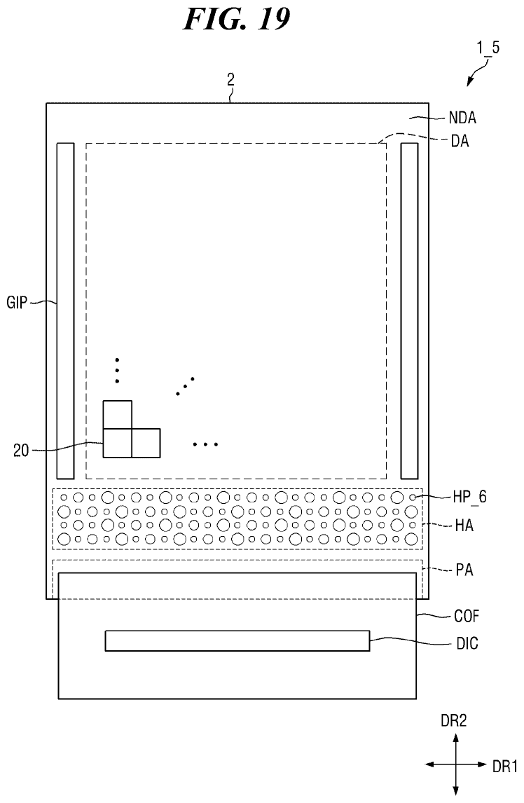

FIG. 19 is a plan view of a display device according to a sixth embodiment.

Referring to FIG. 19, considering that a plurality of groove patterns HP_6 of a display device 1_5 according to the sixth embodiment are not disposed in a matrix form, but is disposed randomly, the display device 1_5 according to the sixth embodiment is different from the display device 1_4 according to FIG. 18.

Other descriptions have been provided with reference to FIGS. 11 to 13, description thereof in more detail is omitted.

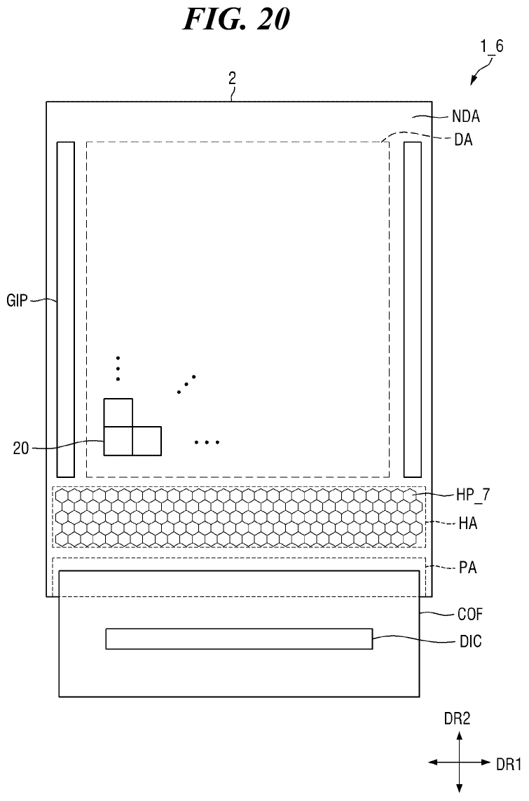

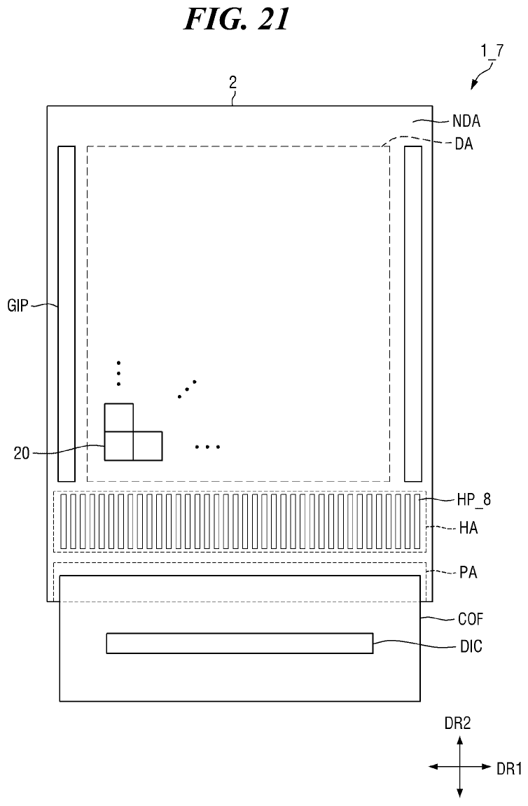

FIG. 20 is a plan view of a display device according to a seventh embodiment.

Referring to FIG. 20, considering that a plurality of groove patterns HP_7 of a display device 1_6 according to the seventh embodiment takes the form of a honeycomb, the display device 1_6 according to the seventh embodiment is different from the display device 1_2 according to FIG. 16. The plurality of groove patterns HP_7 may be disposed in a matrix form, or may be disposed randomly. For example, each of the plurality of groove patterns may be formed in a hexagon shape and arranged to be adjacent to each other, to form the form of the honeycomb. In addition, similar to the embodiment shown in FIG. 18, the plurality of groove patterns HP_7 may have different sizes, and the sizes of the groove patterns HP_7 may become larger as they are closer to the pad area PA.

Other descriptions have been provided with reference to FIGS. 11 to 13, therefore, description thereof in more detail is omitted.

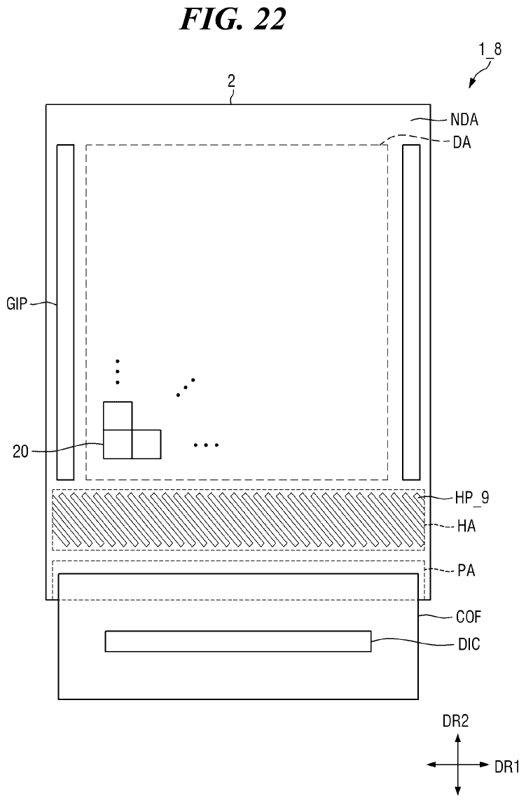

FIG. 21 is a plan view of a display device according to an eighth embodiment.

Referring to FIG. 21, considering that a plurality of groove patterns HP_8 of a display device 1_7 according to the eighth embodiment extends along the second direction DR2, and the adjacent groove patterns HP_8 are spaced apart from each other in the first direction DR1, the display device 1_7 according to the eighth embodiment is different from the display device 1_1 according to FIG. 11.

Other descriptions have been provided with reference to FIGS. 11 to 13, therefore, description thereof in more detail is omitted.

FIG. 22 is a plan view of a display device according to a ninth embodiment.

Referring to FIG. 22, considering that a plurality of groove patterns HP_9 of a display device 1_9 according to the ninth embodiment extend in a direction between the first direction DR1 and the second direction DR2 (or a diagonal direction), the display device 1_9 according to the ninth embodiment is different from the display device 1_1 according to FIG. 11.

Other descriptions have been provided with reference to FIGS. 11 to 13, therefore, description thereof in more detail is omitted.

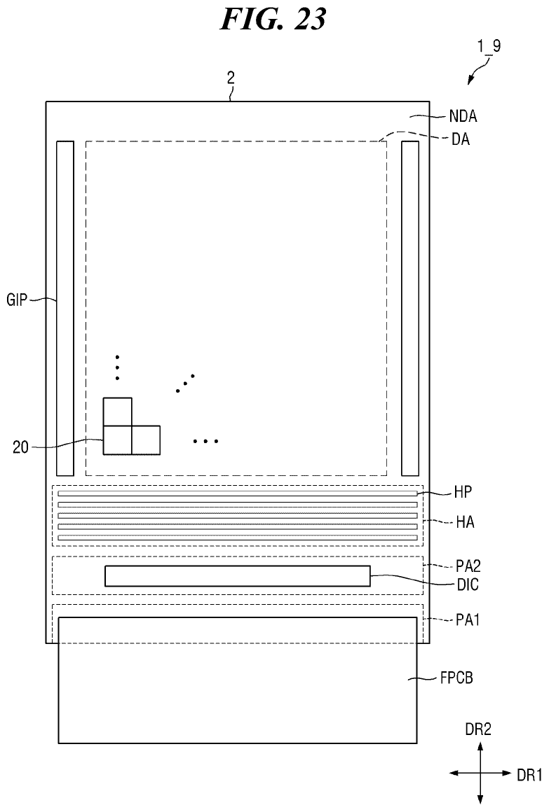

FIG. 23 is a plan view of a display device according to a tenth embodiment.

Referring to FIG. 23, considering that the data driver DIC is attached on a first pad area PA1 of the substrate 2, the display device 1_9 according to the tenth embodiment is different from the display device 1_1 according to the second embodiment.

In more detail, the substrate 2 may include the first pad area PA1, and a second pad area PA2 disposed between the groove area HP and first pad area PA1. A flexible printed circuit board (FPCB) may be attached on the first pad area PA1. The data driver DIC may be disposed in the second pad area PA2.

In case of the display device 1_9 according to the tenth embodiment, during the process for attaching the data driver DIC on the second pad area PA2 of the substrate 2, heat may be supplied to the second pad area PA2. The process for attaching the data driver DIC on the second pad area PA2 may be substantially the same as the process for attaching the printed circuit film COF on the pad area PA according to FIGS. 8 and 9. Therefore, during the process for attaching the data driver DIC on the second pad area PA2, heat provided to the second pad area PA2 may be transferred to the display area DA. However, in case of the display device 1_9 according to the tenth embodiment as well, there is an effect of blocking heat in the groove area HA, because of the arrangement of the groove area HA between the second pad area PA2 and the display area DA. The groove patterns HP formed in the groove area HA may be any one of groove patterns HP_1 to HP_9 shown in FIGS. 14-22.

Other descriptions about the effect by the groove area HA are substantially the same as the description with reference to FIGS. 11 to 13, therefore, the redundant description will be omitted.

In addition, in the display device according to FIGS. 14 to 22, the structure in which the data driver DIC of the display device 1_9 according to FIG. 23 is attached on the first pad area PA1 of the substrate 2 may be applied as well.

The display device according to various embodiments of the present disclosure may be described as below.

One embodiment is a display device according to a first embodiment, including: a display area including pixels; a pad area disposed outside the display area; and a substrate comprising a groove area between the display area and the pad area; and a printed circuit film attached on the pad area, and the groove area may include a groove pattern formed to be convex from a bottom surface of the substrate.

The substrate may include a semiconductor substrate.

The semiconductor substrate may include silicon.

A coarseness level of a surface of the substrate on which the groove pattern is formed may be greater than a coarseness level of a surface of the substrate on which the groove pattern is not formed.

A carbonized surface may be formed more in the groove pattern.

The groove pattern may have a shape of a line extending along a first direction, and the first direction may be orthogonal to a second direction heading for the pad area from the groove area.

The display device may further include: a pad disposed in the pad area on the substrate; and an anisotropic conductive film on the pad, and a bump of the printed circuit film may be electrically connected to the pad through the anisotropic conductive film.

Thermal conductivity of the pad may be 50 W/m·K to 100 W/m·K.

Thermal diffusivity of the substrate may be 0.3 cm2/s to 0.6 cm2/s.

The pixel may include a plurality of subpixels, and may further include organic light emitting diodes disposed on the substrate and disposed in each of the plurality of subpixels.

Another embodiment is a display device, including: a display area including pixels; a pad area disposed outside the display area; and a substrate including a groove area between the display area and the pad area; and a printed circuit film attached on the pad area, and the groove area may include: a first area having a first thickness; and a second area having a second thickness which is smaller than the first thickness.

The groove area may be configured to delay heat generated during a process for attaching the printed circuit film on the pad area.

The display device may further include: a pad disposed in the pad area on the substrate; and an anisotropic conductive film on the pad, and a bump of the printed circuit film may be electrically connected to the pad through the anisotropic conductive film, and the anisotropic conductive film may be melted by the heat.

The substrate may include a semiconductor substrate.

The semiconductor substrate may include silicon.

A coarseness level of a surface of the substrate on which a groove pattern is formed may be greater than a coarseness level of a surface of the substrate on which the groove pattern is not formed.

A carbonized surface may be formed more in the groove pattern.

Thermal conductivity of the pad may be 50 W/m·K to 100 W/m·K.

Thermal diffusivity of the substrate may be 0.3 cm2/s to 0.6 cm2/s.

The pixel may include a plurality of subpixels, and may further include organic light emitting diodes disposed on the substrate and disposed in each of the plurality of subpixels.

From the foregoing description of the first embodiment with reference to accompanying drawings, those skilled in the art to which this disclosure pertains can understand that the present disclosure may be embodied in other specific forms without changing the technical spirit or essential characteristics of the disclosure. In this connection, the above described first embodiment should be understood as exemplary and as not limiting in all aspects. The scope of the claims are not limited by the first embodiment nor the foregoing detailed description generally. In addition, all changes or modified forms derived from the meaning and range of the first embodiment and the equivalents thereof are included in the scope of the claims.

### REFERENCE NUMERALS

1: display device
2: substrate
3: insulation layer
4: first electrode
5: common emitting layer
6: second electrode
7: capping layer
8: encapsulation layer
9: color filter layer
BK: bank
HA: groove area
HP: groove pattern

The various embodiments described above can be combined to provide further embodiments. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device, comprising:
a display area having pixels;
a pad area disposed outside the display area;
a substrate having a groove area between the display area and the pad area; and
a printed circuit film disposed on the pad area,
wherein the groove area includes a groove pattern that is convex from a bottom surface of the substrate.

2. The display device of claim 1, wherein the substrate comprises a semiconductor substrate.

3. The display device of claim 2, wherein the semiconductor substrate comprises silicon.

4. The display device of claim 1, wherein a coarseness of a surface of the substrate including the groove pattern is greater than a coarseness of a surface of the substrate excluding the groove pattern.

5. The display device of claim 4, wherein the groove pattern includes a carbonized surface.

6. The display device of claim 1, wherein the groove pattern includes one or more grooves extending along a first direction, and
wherein the first direction is orthogonal to a second direction, the second direction extending toward the pad area from the groove area.

7. A display device, comprising:
a display area having pixels;
a pad area disposed outside the display area;
a substrate having a groove area between the display area and the pad area; and
a printed circuit film disposed on the pad area,
a pad disposed on the substrate in the pad area; and
an anisotropic conductive film on the pad,
wherein a bump of the printed circuit film is electrically connected to the pad through the anisotropic conductive film.

8. The display device of claim 7, wherein a thermal conductivity of the pad is 50 W/m·K to 100 W/m·K.

9. The display device of claim 7, wherein a thermal diffusivity of the substrate is 0.3 cm2/s to 0.6 cm2/s.

10. The display device of claim 7, wherein the groove pattern includes a plurality of grooves extending into a surface of the substrate.

11. A display device, comprising:
a display area having pixels;
a pad area disposed outside the display area; and
a substrate having a groove area between the display area and the pad area; and
a printed circuit film disposed on the substrate in the pad area,
wherein the groove area includes:
a first area having a first thickness; and
a second area having a second thickness less than the first thickness.

12. The display device of claim 11, wherein the groove area is configured to dissipate heat generated from attaching the printed circuit film to the pad area.

13. The display device of claim 12, further comprising:
a pad disposed on the substrate in the pad area; and
an anisotropic conductive film on the pad,
wherein a bump of the printed circuit film is electrically connected to the pad through the anisotropic conductive film, and
wherein the anisotropic conductive film is melted by the heat.

14. The display device of claim 11, wherein the substrate comprises a semiconductor substrate.

15. The display device of claim 14, wherein the semiconductor substrate comprises silicon.

16. The display device of claim 11, wherein a coarseness of a surface of the substrate including a groove pattern is greater than a coarseness of a surface of the substrate excluding the groove pattern.

17. The display device of claim 16, wherein the groove pattern includes a carbonized surface.

18. The display device of claim 11, wherein a thermal conductivity of the pad is 50 W/m·K to 100 W/m·K.

19. The display device of claim 11, wherein a thermal diffusivity of the substrate is 0.3 cm2/s to 0.6 cm2/s.

20. The display device of claim 11, wherein the groove pattern has a shape comprising a plurality of lines or a plurality of polygon-shaped islands.
